(19) United States
(12) Patent Application Publication
(10) Pub. No.: US 2010/0214513 A1
(43) Pub. Date: Aug. 26, 2010

(54) HIGH CONTRAST DISPLAY

(75) Inventors: Hen-Ta Kang, Taichung City (TW); Wen-Chun Wang, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: WINTEK CORPORATION, Taichung (TW)

(21) Appl. No.: 12/624,432

(22) Filed: Nov. 24, 2009

(30) Foreign Application Priority Data
Feb. 26, 2009 (TW) 98106175

(51) Int. Cl. G02F 1/1334; G02B 26/00; H01L 27/12

(52) U.S. Cl. 349/86; 359/296; 257/59; 257/E27.11

(57) ABSTRACT

A high contrast display having a first substrate, a transistor array substrate and a light shielding layer is provided, wherein the first substrate includes a common electrode. The transistor array substrate includes a plurality of pixels arranged in array, wherein each pixel includes a transistor and a pixel electrode electrically connected thereto. The light shielding layer is disposed between the first substrate and the transistor array substrate. The high contrast display is able to protect the transistors from producing current leakage, so as to improve display quality.

### CROSS-REFERENCE TO RELATED APPLICATION

This application claims the priority benefit of Taiwan application serial no. 98106175, filed on Feb. 26, 2009. The entirety of the above-mentioned patent application is hereby incorporated by reference herein and made a part of this specification.

### BACKGROUND OF THE INVENTION

1. Field of the Invention

The present invention relates to a display apparatus, and more particularly, to a high contrast display.

2. Description of Related Art

FIG. 1A is a schematic downward view of a micro-cup structure of a conventional electrophoretic display, and FIG. 1B is a locally magnified perspective view showing the conventional electrophoretic display shown in FIG. 1A. Referring to FIG. 1A and 1B, a material of the wall structure 130 of the conventional electrophoretic display 100 is a transparent material, and the micro-cup structure 150 filled in display media 140 is composed of black fluids 140b and a plurality of white particles 140a distributed in the black fluid 140b. Referring to FIG. 1B, when an electric field between the common electrodes 112 of the first substrate 110 and each of the pixel electrodes 122 of the transistor array substrate 120 is changed, the movement of the white colored particles 140a is determined to upward or downward opposite to the black fluid 140b according to the electric field is applied to the white colored particles 140a, such that the regions corresponding to the display media 140 then shows a black image or a white image and achieve display effects.

In actual application, according to the consideration of power saving and convenience, the aforesaid electrophoretic display frequently adopts a front light or an external light as a light source whereby a user is able to observe the black display image or the white image. However, as shown in FIG. 1B, after attaching the first substrate 110 and the transistor array substrate 120, a portion of transistors 124 on the transistor array substrate 120 are located underneath of the wall structures 130. As such, since the material of wall structure 130 is a transparent material, light L passing through wall structure 130 enters into the transistor array substrate 120. The light L is reflected by metal layers of the transistor array substrate 120, and then cause the transistor array substrate 120 to produce light-leakage and reduce the display constrat. The light L is then irradiating to the transistors 124 which are located within a projection scope of the transparent wall 130, and thus carriers in the channel region of the transistor 124 absorb the energy of light L. Accordingly, current leakage is generated and thus an abnormal display is observed. In some serious cases, instantaneous great current leakage may cause data lines electrically connected thereto damage, and induce line defects. Hence, drawbacks of conventional electrophoretic display is that transistors thereon are easily influenced by ambient light to cause current leakage.

It can be learned from the above that the conventional electrophoretic display is not likely to prevent the light-leakage due to the reflecting of the external light and to prevent transistors from being influenced by external light to avoid generation of current leakage. Therefore, before the electrophoretic display is extensively applied, manufacturers yearn to resolve issues of the electrophoretic display as to well design a structure of the electrophoretic display for preventing problems of aforesaid current leakage and enhancing the display contrast while using ambient light as light source.

### SUMMARY OF THE INVENTION

The present invention is directed to an array substrate that is able to prevent from current leakage and enhance display contrast.

The present invention is directed to an electrophoretic display that is able to prevent transistors from current leakage and enhance display contrast.

In the present invention, an array substrate including a substrate and a plurality of pixels disposed on the substrate in an array is provided, wherein each pixel comprises a transistor, a pixel electrode electrically connected to the transistor and a light-shielding layer located on the first substrate.

According to an embodiment of the present invention, the light-shielding layer is disposed between the pixel electrodes and the transistors.

In the present invention, a high constrast display including a first substrate, a transistor array substrate, a first electrode, a plurality of display media and a light-shielding layer is provided. The transistor array substrate disposed opposite to the first substrate. The frist electrode disposed on a surface of the first substrate face to the transistor array substrate. The plurality of display media disposed between the first substrate and the transistor array substrate. More specifically, the transistor array substrate comprises a second substrate and a plurality of pixels arranged in an array disposed thereabove, wherein the plurality of display media disposed between the first substrate and the transistor array substrate. The light-shielding layer is disposed between the plurality of display media and the transistors. Other several kinds of the high constrast display provided by the present invention are respectively described in the embodiments.

Since the high constrast display of the present invention has a light-shielding capable of shielding external light, the transistors is protected to prevent from light irradiating and thus is avoid from producing current leakage and enhance display contrast. Moreover, the light-shielding of the present invention is highly compatible with the process of active device array substrate and is able to directly integrate into the process of active device array substrate. Accordingly, it would not spend additional producing costs while improving the display quality of the high constrast display.

To make the above and other objectives, features, and advantages of the present invention more comprehensible, several embodiments accompanied with figures are detailed as follows.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A is a schematic downward view of a micro-cup structure of a conventional electrophoretic display.

FIG. 1B is a locally magnified perspective view showing the conventional electrophoretic display shown in FIG. 1A.

FIG. 2A shows a schematic cross-sectional view of a high contrast display according to an embodiment of the invention.

FIG. 2B shows a schematic cross-sectional view of an electrophoretic display according to an embodiment of the invention.

FIG. 3A shows a locally schematic cross-sectional view of a high contrast display according to another embodiment of the invention.

FIG. 3B shows a locally schematic cross-sectional view of an electrophoretic display according to another embodiment of the invention.

FIGS. 4A and FIG. 5A respectively shows a locally schematic cross-sectional view of a high contrast display according to another embodiment of the invention.

FIGS. 4B and FIG. 5B respectivelyrespectively shows a locally schematic cross-sectional view of an electrophoretic display according to another embodiment of the invention.

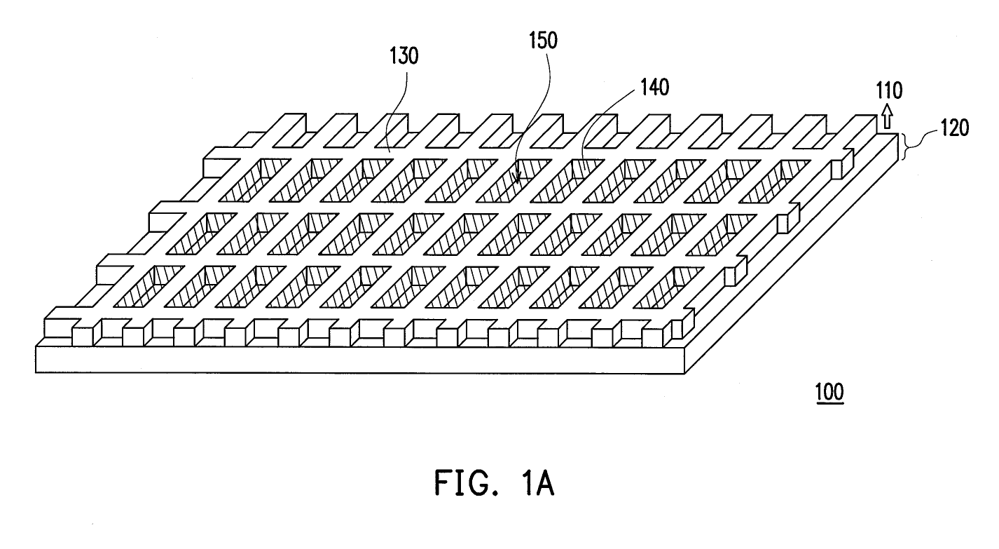

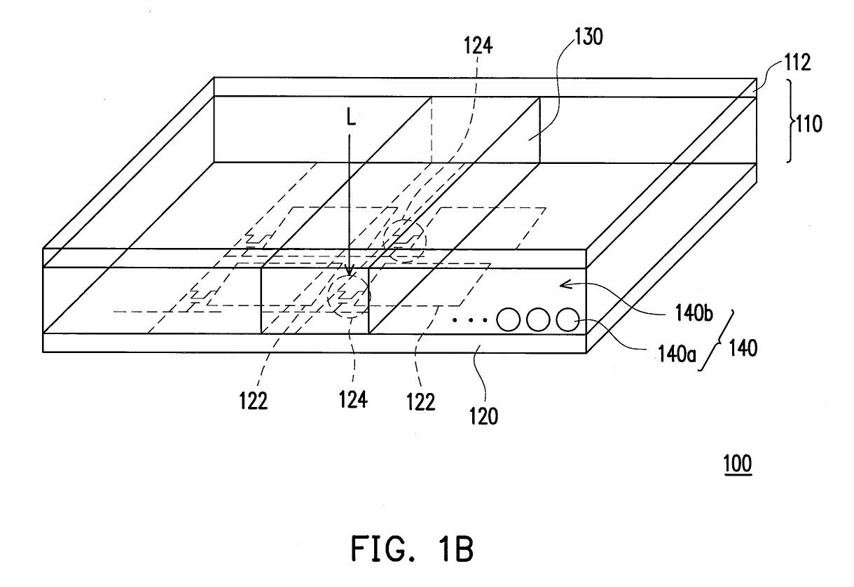

### DESCRIPTION OF EMBODIMENTS

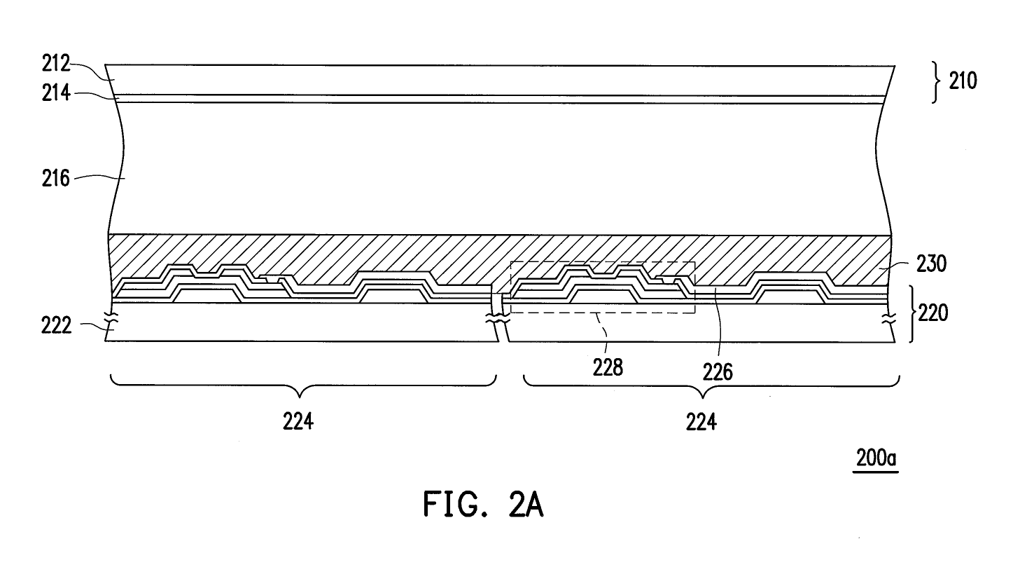

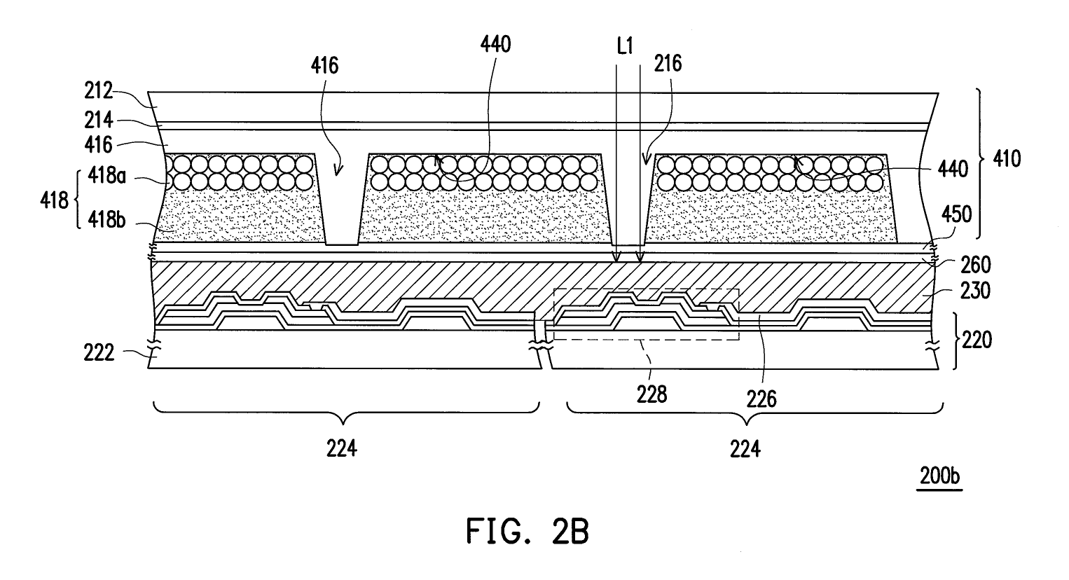

FIG. 2A shows a schematic cross-sectional view of a high constrast display according to an embodiment of the invention. Referring to FIG. 2A, the high constrast display 200a of this embodiment includes a first substrate 210, a transistor array substrate 220, a first electrode 214, a plurality of display media 216. The transistor array substrate 220 is disposed opposite to the first substrate 210. The frist electrode 214 disposed on a surface of the first substrate 210 face to the transistor array substrate 220. The plurality of display media 216 disposed between the first substrate 210 and the transistor array substrate 220, wherein the plurality of display media 216 can be selected from one of cholesteric liquid crystal and polymer dispersed liquid crystal. More specifically, the transistor array substrate 220 comprises a second substrate 222 and a plurality of pixels 224 arranged in an array disposed on the second substrate 222. Each pixel 224 includes a transistor 228 and a pixel electrode 226. The transistor 228 is electrically connected to the pixel electrode 226, wherein the plurality of display media 216 disposed between the first electrode 214 and the pixel electrode 226. The light-shielding layer 230 is disposed between the plurality of display media 216 and the transistors 228. An electrophoretic display is taken as an example to exemplify in the following embodiments, but not intended to limit the present invention. The present invention is capable of applying to various liquid crystal display.

FIG. 2B shows a schematic cross-sectional view of an electrophoretic display according to an embodiment of the invention. Referring to FIG. 2B, the high constrast display 200b of the present embodiment is an electrophoretic display, for example, and mainly includes an electrophoretic substrate 410 served as the first substrate 210, a transistor substrate 220 and a light-shielding layer 230. The electrophoretic substrate 410 and the transistor array substrate 220 respectively have a base 212 and a second substrate 222, wherein the first substrate 212 and the second substrate 222 are respectively able to choose a flexible substrate having flexible characteristics such that the electrophoretic display is constructed to a flexible electrophoretic display. In this embodiment, the electrophoretic substrate 410 includes a common electrode 214, a transparent wall 416 and a plurality of display media 418. The common electrode 214 is located on the first substrate 212. The transparent wall 416 is located on the common electrode 214, so as to define a plurality of micro-cup structures 440 on the common electrode 214. Here, the micro-cup structures 214 are arranged in array, for example. Referring to FIG. 2B, the transistor array substrate 220 includes a plurality of pixels 224 arranged in array and disposed on the second substrate 222, wherein each of the plurality of pixels 224 mainly includes a pixel electrode 226 and a transistor 228 controlling the pixel electrode 226, wherein the transistor 228 is a thin film transistor, for example.

As indicated in FIG. 2B, the plurality of display media 418 is located between the common electrode 214 and the plurality of pixel electrodes 226, and the display colors of regions corresponding to the display media 418 is determined upon an electric field between the corresponding pixel electrode 226 and the common electrode 214. Besides, the light-shielding layer 230 is disposed between the electrophoretic substrate 410 and the plurality of transistors 228, so as to block a light from the transparent wall 416 to irradiate to transistors 228. Moreover, the electrophoretic substrate 410 may selectively choose a protective layer 450 to cover the transparent wall 416 and display media 418 on the first substrate 212, and then attach the electrophoretic substrate 410 to the transistor array substrate 220 by an adhesive layer 260.

Please refer to FIG. 2B, each of the micro-cup structures 440 is filled with the each of display media 418, respectively, and each of the display media 418 has a plurality of colored particles 418a. More specifically, each of the display media 418 is mainly constituted by the fluid 418b and colored particles 418a , wherein the fluid 418b and colored particles 418a are in different colors. The micro-cup structures 440 are filled with the fluid 418b, and the colored particles 418a are distributed in the fluid 418b. In terms of white particles and a black fluid, when a voltage difference exists between the common electrodes 214 and the pixel electrodes 226 which are respectively two sides of the display media 418, the colored particles 418a move relative to the fluid 418b in accordance with the direction at which the electric field is applied to the colored particles 418a, such that the colored particles 418a of each of the display media 418 adjacent to the first substrate 212 are changed in number, and that each of the display media 418 displays the black color image or the white color image so as to achieve display effect.

It should be notice that the light-shielding 230 of the electrophoretic display of the present invention disposes between the transistors 228 and the electrophoretic substrate 410. As such, a light passing through the transparent wall 416 is shield to prevent arriving transistors 228 by the light-shielding 230, such that the transistors 228 is prevent from light irradiation. Therefore, the carriers of the transistors 228 are able to operate normally so as to prevent generation of current leakage and enhance display contrast. Note that the light-shielding layer 230 of the present embodiment covers the pixel electrodes 226 and the transistors 228 as one piece and no patterning process is required. Therefore, the process of the electrophoretic display is simple. Of Course, the light-shielding layer 230 of the present invention in other embodiments may only cover one side of thin film transistors 228 adjacent to the electrophoretic substrate 410 rather than covers the second substrate 222 as one piece. Or, the light-shielding layer 230 may also only cover those transistors 228 located underneath the transparent wall 416, such that lights passing through the transparent wall 416 is shield to avoid light irradiating to transistors 228, and thus generation of current leakage is prevented and the display quality of the electrophoretic display is kept highly. Accordingly, the layout coverage of light-shielding layer 230 in the high constrast display 200b of the present invention is not limited. In brief, in a downward direction of the electrophoretic display, the coverage of the light-shielding layer 230 is only required to satisfy the relationship that at least coverage of the light-shielding layer 230 covers overlapping regions of the transparent wall 416 and transistors 228.

Certainly, the light-shielding layer 230 may integrate directly into any process flow of transistor array substrate 220. More specifically, in a cross-sectional direction of the electrophoretic display, the light-shielding 230 is only required to cover a side of transistors 228 adjacent to the electrophoretic substrate 410. In other words, the light-shielding layer 230 is able to place into any layer located between the transistors 228 and the first substrate 212 according to the requirement of products and process. Base on the aforesaid description, the design of the light-shielding 230 of the present invention in the downward direction of the high constrast display 200b is satisfied that the light-shielding 230 at least covers the overlapping regions of the transparent walls 416 and transistors 228. Besides, the design of the light-shielding 230 of the present invention in a thickness direction of composed layers of the high constrast display 200b is located to one side of the transistors 228 adjacent to the first substrate 212. As such, the high constrast display 200b of the present invention is able to avoid external light interference by using the light-shielding layer 230 to shield external light, and thus the origin device characteristics of the transistors 228 is kept and damages of the transistors 228 causing from current leakage is avoid and the display contrast is enhanced.

As indicated in FIG. 2B, since the indicated in FIG. 2B, the light-shielding layer 230 is located between the transparent walls 416 and the transistors 228, and the coverage of the light-shielding layer 230 contains the overlapping regions of the transparent walls 416 and the transistors 228. Hence, the light-shielding layer 230 is suitable to shield the incident light L1 irradiating from the first substrate 212. Accordingly, the transistors 228 covered by the light-shielding layer 230 is prevented from light irradiating, so as to keep device characteristics thereof and being operated normally. Moreover, in practice, a material of the light-shielding layer 230 can be selected from materials having light-shielding effects. In terms of dielectric materials, black resin can be used, which should not be construed as limited to the present invention.

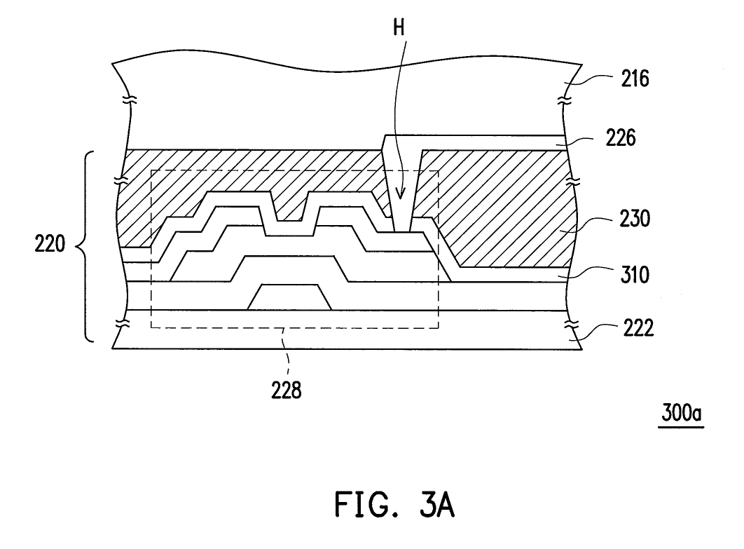

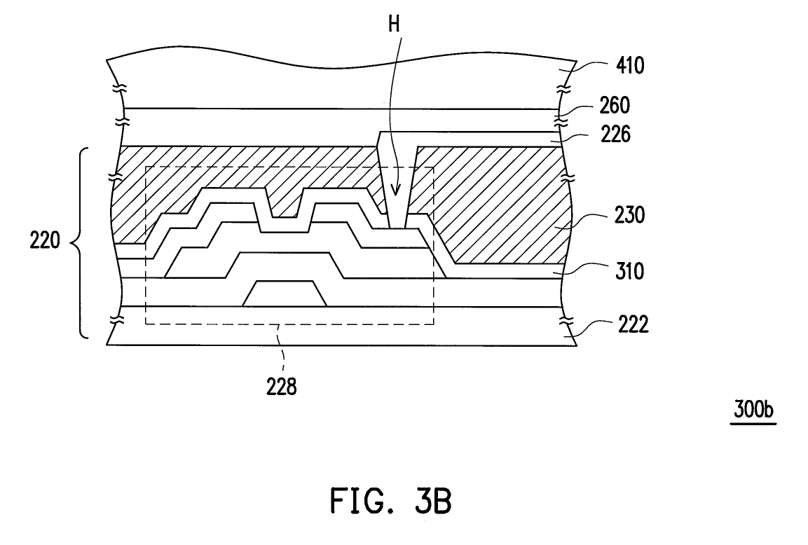

FIG. 3A`3B shows a locally schematic cross-sectional view of high contrast displays according to another embodiment of the invention, wherein the difference between FIG. 3A and FIG. 3B is that the first substrate of the electrophoretic display 300b illustrated in FIG. 3B is an electrophoretic substrate 410. Referring to FIG. 3A, the light-shielding layer 230 of the high contrast display 300a of the present embodiment is located between the pixel electrodes 226 and the transistors 228. In detail, in this embodiment, the transistor array substrate 220 has a passivation 310 covering the transistors 228, and the pixel electrodes 226 electrically connect to the corresponding transistors 228 through the corresponding openings H of the passivation layer 310. As indicated in FIG. 3A, the light-shielding layer 230 is located between the passivation layer 310 and the pixel electrodes 226. In other words, in the high contrast display 300a of the present embodiment, a stacked layer composed of the light-shielding layer 230 and the passivation layer 310 is disposed between the transistors 228 and the pixel electrodes 226. The light-shielding layer 230 exposes the openings H of the passivation 310 so that the pixels electrodes 226 electrically connect to transistors 228 through the common opening of the light-shielding layer 230 and the passivation layer 310. In this embodiment, a material of the light-shielding layer 230 is different from that of the passivation layer 310. Of course, positioning of the light-shielding layer 230 of the present embodiment can be exchanged with that of the passivation layer 310 which is able to prevent light irradiating to transistors and achieve light shielding effect and enhance display contrast as well.

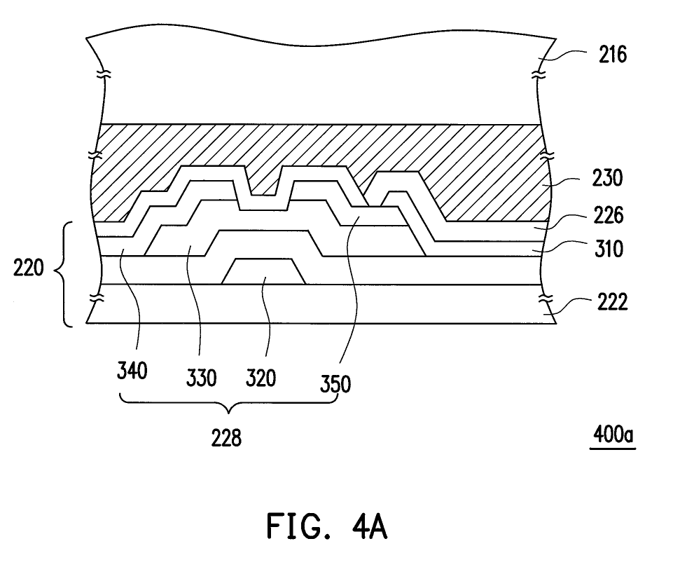

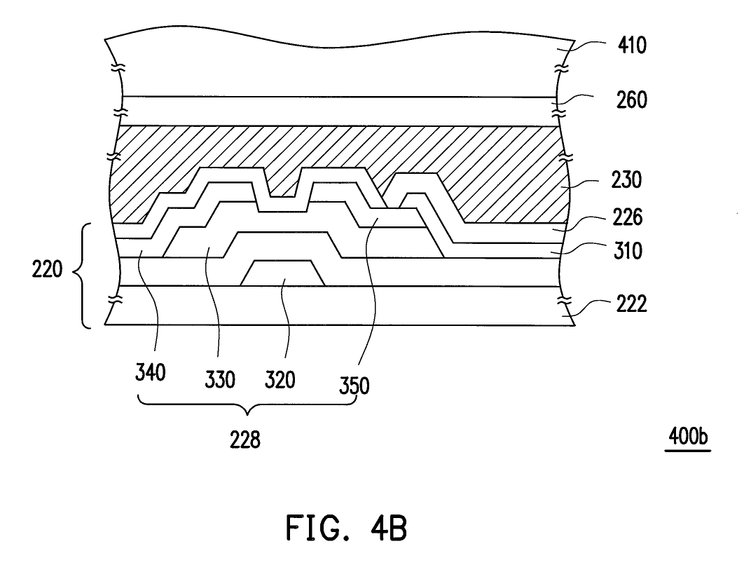

FIG. 4A`4B respectively shows a locally schematic cross-sectional view of high contrast displays according to another embodiment of the invention, wherein the difference between FIG. 4A and FIG. 4B is that the first substrate of the electrophoretic display 400b illustrated in FIG. 4B is an electrophoretic substrate 410. Referring to FIG. 4A, compare to the aforesaid embodiments, the light-shielding layer 230 of the high contrast display 400a covers the pixels electrodes 226 and the transistors 228.

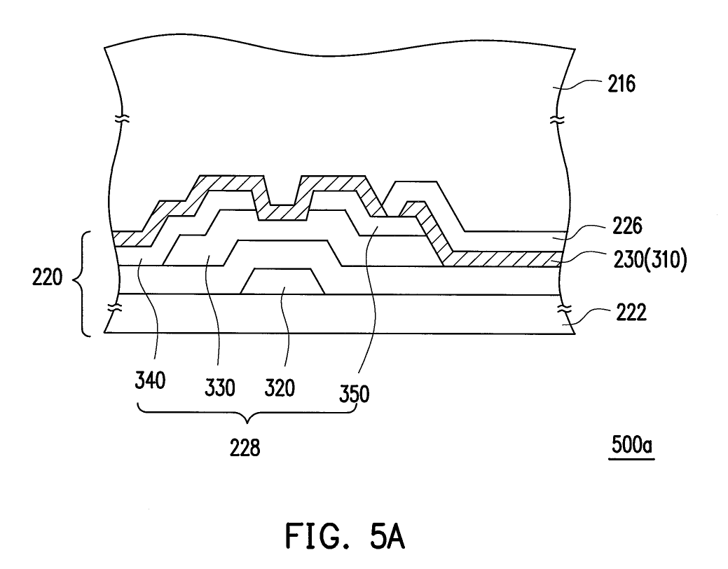

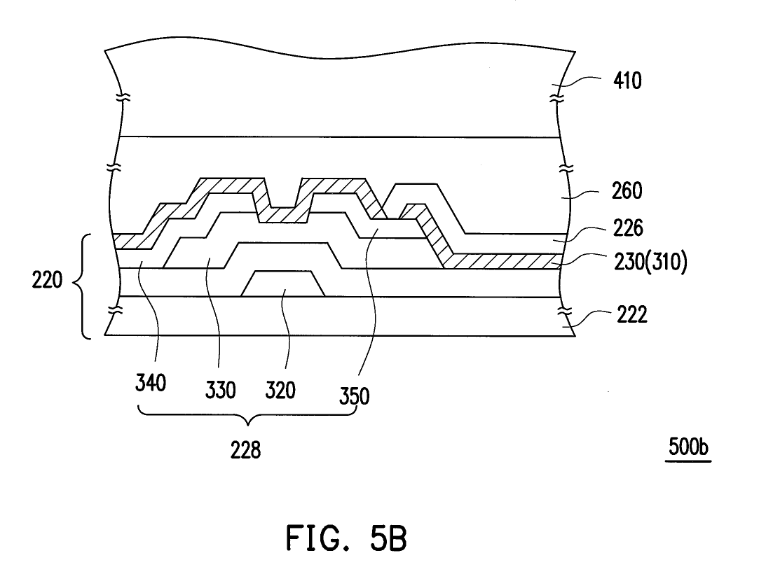

FIG. 5A`5B respectively shows a locally schematic cross-sectional view of high contrast displays according to another embodiment of the invention, wherein the difference between FIG. 5A and FIG. 5B is that the first substrate of the electrophoretic display 500b illustrated in FIG. 5B is an electrophoretic substrate 410. Referring to FIG. 5A, compare to the aforesaid embodiments, the passivation layer 310 of the hihg contrast display 500a of the present embodiment is directly fabricated by a light-shielding material. In other words, only one single passivation layer 310 is disposed between the transistors 228 and the pixel electrodes 226, and the passivation layer 310 can play a role of light-shielding layer 230 as well. That is to say, the passivation layer 310 has light-shielding effect. Therefore, in the present embodiment, the passivation layer 310 of the high contrast display 500a located above the transistors 228 has a light-shielding function, such that the passivation layer 310 having light-shielding function can shield light and reduce the influence caused from the external light applied to transistors 228, and the current leakage is prevented.

Furthermore, as indicated in FIG. 5A, each of the transistors 228 mainly includes a gate 320, a channel layer 330, a source 340 and a drain 350, wherein the channel layer 330 is located above the gate 320, the source 340 and the drain 350 are located on the channel layer 330 respectively above two sides of the gate 320, and the pixel electrodes 226 electrically connects to the drain 350 through the opening H of the passivation layer 310. In the aforesaid embodiment, the light-shielding layer 230 of the high contrast display 500a covers the transistors 228 entirely, that is to say, the light-shielding layer 230 covers the source 340 and the drain 350. Noted that since the current leakage is mainly generated in regions of channel layers 330 in the transistors, the light-shielding layer 230 of the present invention also can only dispose above and cover the channel layers 330 of transistors 228. In other words, in this application, the light-shielding layer 230 and the channel layers 330 can be fabricated by performing the same mask process, wherein the light-shielding layer 230 is highly compatible with the process of transistor array substrate 220. Accordingly, the mask production fee is not additional increased, and thus the production cost can be saved.

In summary, the high constrast display provided in the present invention have at least the following advantages:

1. The high constrast display of the present invention has the light-shielding layer capable of shielding light which irradiates from external light. Hence, the high constrast display of the present invention can efficiently prevent current leakage. When the intensity of the ambient light is vivid, the high constrast display of the present invention can efficiently prevent data lines from damage causing from current leakage and thus maintain the display quality. Moreover, since the light-shielding layer of the high constrast display has ight-shielding function, the constast of the high constrast display is able to be enhanced.

2. The high constrast display of the present invention is highly compatible with the process of active device array substrate and is able to directly integrate into the process of active device array substrate. Hence, the high constrast display of the present invention can give consideration to improving display quality and production cost.

3. The high constrast display of the present invention is not limited to the applying filed. The high constrast display can be applied to electrophoretic display or various types of liquid crystal display. When the intensity of the ambient light is vivid, the high constrast display of the present invention can efficiently prevent data lines from damage causing from current leakage and thus maintain the display quality.

Although the present invention has been disclosed by the above embodiments, they are not intended to limit the present invention. Anybody skilled in the art may make some modifications and alterations without departing from the spirit and scope of the present invention. Therefore, the protection range of the present invention falls in the appended claims.

What is claimed is:

1. An array substrate, comprising:
a substrate; and
a plurality of pixels disposed on the substrate in an array, wherein each pixel comprises:
a transistor;
a pixel electrode electrically connected to the transistor,
a light-shielding layer located on the transistor.

2. The array substrate as claimed in claim 1, wherein the light-shielding layer is disposed between the pixel electrodes and the transistors.

3. A display, comprising:
a first substrate;
a transistor array substrate disposed opposite to the first substrate, wherein the transistor array substrate comprises:
a second substrate;
a plurality of pixels arranged in an array, wherein the pixel comprises:
a transistor;
a pixel electrode electrically connected to the transistor;
a frist electrode disposed on a surface of the first substrate face to the transistor array substrate;
a plurality of display media disposed between the first substrate and the transistor array substrate, wherein the plurality of display media is disposed between the first electrode and the pixel electrodes; and
a light-shielding layer located between the display medium and the transistors.

4. The display as claimed in claim 3, wherein the display medium is one of the cholesteric liquid crystal and polymer dispersed liquid crystal.

5. The display as claimed in claim 3, further comprising a transparent wall disposed on the first electrode to define a plurality of micro-cup structures, wherein the plurality of display media respectively filling each of the micro-cup structures, and each of the display media having a plurality of colored particles.

6. The display as claimed in claim 5, further comprising a protective layer located on the first substrate, the protective layer covers the transparent wall.

7. The display as claimed in claim 5, further comprising an adhesive layer located between the first substrate and the transistor array substrate.

8. The display as claimed in claim 3, wherein the light-shielding layer comprises a black dielectric layer.

9. The display as claimed in claim 3, wherein the light-shielding layer covers the second substrate as one piece.

10. The display as claimed in claim 3, wherein the light-shielding layer is located between the pixel electrodes and the transistors.

11. The display as claimed in claim 3, wherein the transistor substrate has a passivation layer covering the transistors, the passivation layer located above each of the transistors respectively has an opening, each of the pixel electrodes electrically connects to the corresponding transistors through each of the openings.

12. The display as claimed in claim 11, wherein a stacked layer composed of the light-shielding layer and the passivation layer is disposed between the transistors and the pixel electrodes, a material of the light-shielding layer is different from that of the passivation layer.

13. The display as claimed in claim 11, wherein the passivation layer is only composed of the light-shielding layer, and a material of the light-shielding layer is the same with that of the passivation layer.

14. The display as claimed in claim 3, wherein each of the transistors comprises a gate, a channel layer, a source and a drain, the channel layer is located above the gate, the source and the drain are located on the channel layer above two sides of the gate, and the light-shielding layer is only located above the channel layer.

15. The display as claimed in claim 3, wherein each of the plurality of display media comprises a fluid and the plurality of colored particles.

16. The panel display apparatus as claimed in claim 3, wherein the first substrate is a flexible substrate.

17. The panel display apparatus as claimed in claim 3, wherein the second substrate is a flexible substrate.
